(19) United States
(12) Patent Application Publication
(10) Pub. No.: US 2011/0048520 A1
(43) Pub. Date: Mar. 3, 2011

(54) HIGH EFFICIENCY SOLAR CELL WITH A SILICON SCAVENGER CELL

(76) Inventors: Allen M. Barnett, Landenberg, PA (US); Roger Buelow, Gates Mills, OH (US); James B. Oliver, Pittsford, NY (US); David B. Salzman, Bethesda, MD (US); Laszlo A. Takacs, Ashtabula, OH (US)

(21) Appl. No.: 12/942,596

(22) Filed: Nov. 9, 2010

Related U.S. Application Data
(63) Continuation of application No. 12/358,913, filed on Jan. 23, 2009, now abandoned.
Application No. 12/358,913 is a continuation of application No. PCT/US2007/016680, filed on Jul. 25, 2007.
(60) Provisional application No. 60/833,994, filed on Jul. 28, 2006.

(51) Int. Cl. H01L 31/101

(52) U.S. Cl. 136/255

(57) ABSTRACT

This invention relates to an improved high efficiency solar cell with a “HEGC stack-dichroic mirror-MEGC stack” architecture or a “HEGC stack-dichroic mirror-MEGC stack-LEGC stack” architecture. The improvement comprises the addition of a silicon cell to act as a scavenger cell to absorb light that would otherwise not be absorbed and to convert that energy to electricity. The silicon cell is positioned adjacent to the cell with the smallest energy gap of the cells in the MEGC stack.

### CROSS-REFERENCE TO RELATED APPLICATION

This application is a Continuation of International Application Number PCT/US2007/016680, filed Jul. 25, 2007, which claims priority to U.S. Provisional application No. 60/833,994, filed Jul. 28, 2006 (now expired).

This invention was made with Government support under Agreement W911NF-05-9-0005 awarded by the Government. The Government has certain rights in the invention.

The invention claimed herein was made pursuant to the Articles of Collaboration for the 50% Efficient Solar Cells Consortium formed pursuant to the Defense Advanced Research Projects Agency (DARPA) award to the University of Delaware Oct. 1, 2005, W911NF-05-9-0005.

### FIELD OF THE INVENTION

This invention relates to an improved high efficiency solar cell with a silicon scavenger cell. This solar cell is suitable for use in both mobile and stationary applications.

### BACKGROUND OF THE INVENTION

Solar cell development has been in progress for over fifty years. One-junction silicon solar cells have received much attention over that period and are used in terrestrial photovoltaic applications. However, a one-junction silicon solar cell captures less than half of the theoretical potential for solar energy conversion with the best laboratory solar cells currently providing only about 24.7% efficiency. This limits the application of such cells.

High performance photovoltaic systems are required for both economic and technical reasons. The cost of electricity can be halved by doubling the efficiency of the solar cell. Many applications do not have the area required to provide the needed power using current solar cells.

Two types of solar cell architecture have been proposed for more efficient solar cells. One is a lateral architecture. An optical dispersion element is used to split the solar spectrum into its wavelength components. Separate solar cells are placed under each wavelength band and the cells are chosen so that they provide good efficiency for light of that wavelength band. Another architecture is a vertical one in which individual solar cells with different energy gaps are arranged in a stack. These are commonly referred to as cascade, tandem or multiple junction cells The solar light is passed through the stack.

There is a need for the development of high efficiency solar cells.

### SUMMARY OF THE INVENTION

This invention provides an improved high efficiency solar cell with a “high energy gap cell (HEGC) stack-dichroic mirror-mid energy gap cell (MEGC) stack” architecture or a “high energy gap cell (HEGC) stack-dichroic mirror-mid energy gap cell (MEGC) stack-low energy gap cell (LEGC) stack” architecture, the improvement comprising a silicon cell positioned adjacent to the cell with the smallest energy gap of the cells in the MEGC stack.

### BRIEF DESCRIPTION OF THE FIGURES

FIG. 1 shows a schematic drawing of a cell stack.

FIG. 2 illustrates an embodiment of the improved solar cell with the “HEGC stack-dichroic mirror-MEGC stack” architecture with a dichroic mirror that reflects light with photons of energy ≧E_{g}^{m} and transmits light with photons of energy <E_{g}^{m} and with a silicon cell contiguous to the MEGC stack.

FIG. 3 illustrates an embodiment of the improved solar cell with the “HEGC stack-dichroic mirror-MEGC stack-LEGC stack” architecture with a dichroic mirror that reflects light with photons of energy ≧E_{g}^{m} and transmits light with photons of energy <E_{g}^{m} and with a silicon cell contiguous to the MEGC stack.

### DETAILED DESCRIPTION OF THE PREFERRED EMBODIMENTS

The instant invention provides an improved high efficiency solar cell. The improved high efficiency solar cell has an efficiency in excess of 30% and, preferably, up to and surpassing 50%. In one embodiment the improved solar cell has the “HEGC stack-dichroic mirror-MEGC stack” architecture. In another embodiment the improved solar cell has the “HEGC stack-dichroic mirror-MEGC stack-LEGC stack” architecture. The improvement is the addition of a silicon cell to act as a scavenger cell to absorb light that would otherwise not be absorbed and to convert that energy to electricity. The silicon cell provided by this invention increases the efficiency of the solar cell.

In one embodiment, the solar cell with the “HEGC stack-dichroic mirror-MEGC stack” architecture or the “HEGC stack-dichroic mirror-MEGC stack-LEGC stack” architecture is comprised of a high energy gap cell and a dichroic mirror to split the light transmitted by the high energy gap cell. In this solar cell architecture, the exposure of a high energy gap cell to the solar light before there is any splitting of the solar light into spectral components by a dispersion device plays a key role in enabling the achievement of a high efficiency solar cell and in providing various embodiments of the solar cell. This architecture provides efficient use of all portions of the solar spectrum in a manner that enables a practical high efficiency solar cell. The high energy cell absorbs the higher energy photons of energy ≧E_{g}^{h}, i.e., the blue-green to ultraviolet portion of the solar light, and converts that energy into electricity. The high energy cell is transparent to and transmits the photons of energy <E_{g}^{h}. Spectral splitting of the remaining light, i.e., the light transmitted by the high energy gap cell, is then performed by means of the dichroic mirror. Since the blue-green to ultraviolet light has been absorbed by the high energy gap cell before the spectral splitting, requirements for the dichroic mirror are relaxed. Therefore improved and less costly splitting of the remaining light can be achieved. Requirements on the cells used to absorb the remaining light and convert that energy into electricity are also relaxed. As a result a practical, high efficiency solar cell can be achieved.

The dichroic mirror operating at E_{g}^{m} is positioned so that the light transmitted by the high energy gap cell impinges upon the dichroic mirror. The so-called “cold” dichroic mirror reflects light with photons of energy ≧E_{g}^{m} and transmits light with photons of energy <E_{g}^{m}. The so-called “hot” dichroic mirror transmits light with photons of energy ≧E_{g}^{m} and reflects light with photons of energy <E_{g}^{m}. The light reflected by and transmitted by the dichroic mirror can then be absorbed by other cells and the energy converted into electricity.

In another embodiment, the high energy gap cell upon which the solar light impinges is one of two or more high energy gap cells with different energy gaps all of which are ≧E_{g}^{h}. The cells are arranged vertically in a HEGC stack in descending order of their energy gaps with the first cell having the largest energy gap. The first cell absorbs photons of energy greater than or equal to its energy gap and is transparent to and transmits photons of energy less than its energy gap. The second cell in the stack has a lower energy gap than the first cell and absorbs photons of energy greater than or equal to its energy gap and is transparent to and transmits photons of energy less than its energy gap. Similarly with any other cells present in the stack. In this embodiment, the dichroic mirror operating at E_{g}^{m} is positioned so that the light transmitted by the HEGC stack impinges upon the dichroic mirror. Again, the light reflected by and transmitted by the dichroic mirror can then be absorbed by other cells and the energy converted into electricity. The description of a HEGC stack that contains one or more cells with different energy gaps arranged vertically in descending order of their energy gaps with the first cell having the largest energy gap of the one or more cells in the HEGC stack cells, wherein solar light impinges upon the surface of the first cell in the HEGC stack, wherein the energy gap of each cell in the HEGC stack is ≧E_{g}^{m} and wherein the one or more cells in the HEGC stack each absorb light with photons of energy greater than or equal to their energy gap and are transparent to and transmit light with photons of energy less than their energy gap encompasses both of the above described embodiments, that having only one high energy gap cell and that having more than one high energy gap cell.

The solar cell with the “HEGC stack-dichroic mirror-MEGC” stack architecture is comprised of a mid energy gap cell MEGC stack in addition to the HEGC stack and the dichroic mirror. The component of light with photons of energy ≧E_{g}^{m} provided by the dichroic mirror is arranged to impinge upon the MEGC stack. As used herein, a solar cell with the “HEGC stack-dichroic mirror-MEGC stack” architecture is a solar cell comprising:
(a) a HEGC stack that contains one or more cells with different energy gaps arranged vertically in descending order of their energy gaps with the first cell having the largest energy gap of the one or more cells in the HEGC stack, wherein solar light impinges upon the surface of the first cell in the HEGC stack before there is any splitting of the solar light into spectral components, wherein the energy gap of each cell in the HEGC stack is ≧E_{g}^{h} and wherein the one or more cells in the HEGC stack each absorb light with photons of energy greater than or equal to their energy gap and are transparent to and transmit light with photons of energy less than their energy gap thereby providing light transmitted by the HEGC stack;
(b) a dichroic mirror operating at E_{g}^{m} and positioned so that the light transmitted by the HEGC stack impinges upon the dichroic mirror, wherein E_{g}^{m}<E_{g}^{h} and wherein the dichroic mirror provides a separation of the light transmitted by the HEGC stack into two spectral components, one component of light with photons of energy ≧E_{g}^{m} and one component of light with photons of energy <E_{g}^{m} and wherein one of these components is reflected by the dichroic mirror and one is transmitted by the dichroic mirror; and
(c) a MEGC stack that contains one or more cells with different energy gaps arranged vertically in descending order of their energy gaps with the first cell having the largest energy gap of the one or more cells in the MEGC stack, the MEGC stack being positioned so that the component of light with photons of energy ≧E_{g}^{m} impinges upon the surface of the first cell in the MEGC stack, wherein the energy gap of each cell in the MEGC stack is ≧E_{g}^{m} and <E_{g}^{h} and wherein the one or more cells in the MEGC stack each absorb light with photons of energy greater than or equal to their energy gap and are transparent to and transmit light with photons of energy less than their energy gap.

The solar cell with the “HEGC stack-dichroic mirror-MEGC stack-LEGC stack” architecture is comprised of a MEGC stack and a LEGC stack in addition to the HEGC stack and the dichroic mirror. The component of light with photons of energy ≧E_{g}^{m} provided by the dichroic mirror is arranged to impinge upon the MEGC stack and the component of light with photons of energy <E_{g}^{m} provided by the dichroic mirror is arranged to impinge upon the LEGC stack. As used herein, a solar cell with the “HEGC stack-dichroic mirror-MEGC stack-LEGC stack” architecture is a solar cell comprising:
(a) a HEGC stack that contains one or more cells with different energy gaps arranged vertically in descending order of their energy gaps with the first cell having the largest energy gap of the one or more cells in the HEGC stack, wherein solar light impinges upon the surface of the first cell in the HEGC stack before there is any splitting of the solar light into spectral components, wherein the energy gap of each cell in the HEGC stack is ≧E_{g}^{h} and wherein the one or more cells in the HEGC stack each absorb light with photons of energy greater than or equal to their energy gap and are transparent to and transmit light with photons of energy less than their energy gap thereby providing light transmitted by the HEGC stack;
(b) a dichroic mirror operating at E_{g}^{m} and positioned so that the light transmitted by the HEGC stack impinges upon the dichroic mirror, wherein E_{g}^{m}<E_{g}^{h} and wherein the dichroic mirror provides a separation of the light transmitted by the HEGC stack into two spectral components, one component of light with photons of energy ≧E_{g}^{m} and one component of light with photons of energy <E_{g}^{m} and wherein one of these components is reflected by the dichroic mirror and one is transmitted by the dichroic mirror;
(c) a MEGC stack that contains one or more cells with different energy gaps arranged vertically in descending order of their energy gaps with the first cell having the largest energy gap of the one or more cells in the MEGC stack, the MEGC stack being positioned so that the component of light with photons of energy ≧E_{g}^{m} impinges upon the surface of the first cell in the MEGC stack, wherein the energy gap of each cell in the MEGC stack is ≧E_{g}^{m} and <E_{g}^{h} and wherein the one or more cells in the MEGC stack each absorb light with photons of energy greater than or equal to their energy gap and are transparent to and transmit light with photons of energy less than their energy gap; and
(d) a LEGC stack that contains one or more cells with different energy gaps arranged vertically in descending order of their energy gaps with the first cell having the largest energy gap of the one or more cells in the LEGC stack, the LEGC stack being positioned so that the component of light with photons of energy <E_{g}^{m} impinges upon the surface of the first cell in the LEGC stack, wherein the energy gap of each cell in the LEGC stack is <E_{g}^{m} and wherein the one or more cells in the LEGC stack each absorb light with photons of energy greater than or equal to their energy gap and are transparent to and transmit light with photons of energy less than their energy gap.

Preferably, in both of the above architectures, E_{g}^{m} is about equal to the energy gap of the cell with the lowest energy gap in the MEGC stack

“Cell” is used herein to describe the individual cells that are contained in the various stacks of the solar cell and to describe the silicon cell adjacent to the MEGC stack. These cells are generally referred to as solar cells. The term “solar cell” is used herein to describe the complete device.

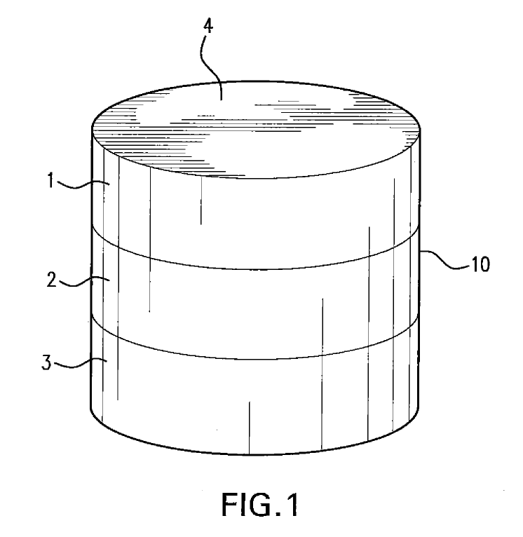

As indicated above, as used herein, “arranged vertically in descending order of their energy gaps with the first cell having the largest energy gap of the cells in the stack” means that the cells in the stack are arranged sequentially with the first cell having the largest energy gap, the second cell directly below the first cell having the next largest energy gap, the third cell directly below the second cell having the third largest energy gap, etc. This arrangement of a cell stack is shown schematically in FIG. 1. The cell stack 10 has three cells, 1, 2 and 3, with cell 1 being the first cell. The energy gaps of the three cells are such that E_{g}¹>E_{g}²>E_{g}³ where E_{g}¹ is the energy gap of cell 1, E_{g}² is the energy gap of cell 2 and E_{g}³ is the energy gap of cell 3. Cell 1 will absorb the light with photons of energy ≧E_{g}¹ and transmit the light with photons of energy <E_{g}¹. Cell 2 will absorb the light with photons of energy ≧E_{g}² and transmit the light with photons of energy <E_{g}². Similarly with cell 3. The cells convert the energy of the absorbed photons into electricity.

“Absorbed” as used herein means that a photon absorbed by the cell results in the creation of an electron-hole pair.

“The dichroic mirror operating at E_{g}^{m}″ is used herein to mean that the dichroic mirror provides a separation of the light transmitted by the HEGC stack into two spectral components, one component of light with photons of energy ≧E_{g}^{m} and one component of light with photons of energy <E_{g}^{m}. One of these components is reflected by the dichroic mirror and one is transmitted by the dichroic mirror. A “cold” dichroic mirror reflects light with photons of energy ≧E_{g}^{m} and transmits light with photons of energy <E_{g}^{m} and a “hot” dichroic mirror transmits light with photons of energy ≧E_{g}^{m} and reflects light with photons of energy <E_{g}^{m}. Typically the dichroic mirror will be positioned so that it is not perpendicular to the light transmitted by the HEGC stack. In this way the direction of the reflected light is not directly back toward the HEGC stack but is rather at an angle with respect to the direction of the light impinging on the dichroic mirror and the reflected light can more readily be arranged to impinge upon other cells. The transition from transmission to reflection occurs over a range of energides and corresponding wavelengths. The operating energy E_{g}^{m} is taken as the midpoint of this transition region. Unless the transition is extremely sharp, it is recognized that some photons of energy >E_{g}^{m} will be transmitted and some photons of energy <E_{g}^{m} will be reflected. In the transition range, the majority of photons with energies greater than E_{g}^{m} are reflected; the majority of photons with energies less than E_{g}^{m} are transmitted. The above definition of “the dichroic mirror operating at E_{g}^{m}″ should be understood and interpreted in terms of this recognition of the nature of the transition region. For a given dichroic mirror, the operating energy shifts to lower energies (higher wavelengths) as the dichroic mirror is rotated away from being perpendicular to the direction of incidence of the light beam impinging upon it and “the dichroic mirror operating at E_{g}^{m}″ should be understood and interpreted to apply to the position in which the dichroic mirror is placed relative to the direction of the impinging light. A dichroic mirror is a multilayer structure, typically containing 20 or more alternate layers of two transparent oxides. A sharper transition requires more layers and higher cost.

The MEGC stack contains one or more cells with different energy gaps arranged vertically in descending order of their energy gaps with the first cell having the largest energy gap of the one or more cells in the MEGC stack. The MEGC stack is positioned so that the component of light with photons of energy ≧E_{g}^{m} impinges upon the surface of the first cell in the MEGC stack. The energy gap of each cell in the MEGC stack is ≧E_{g}^{m} and <E_{g}^{h}. The one or more cells in the MEGC stack each absorb light with photons of energy greater than or equal to their energy gap and are transparent to and transmit light with photons of energy less than their energy gap. Preferably, the MEGC stack contains at least two cells.

The LEGC stack contains one or more cells with different energy gaps arranged vertically in descending order of their energy gaps with the first cell having the largest energy gap of the one or more cells in the LEGC stack. The LEGC stack is positioned so that the component of light with photons of energy <E_{g}^{m} impinges upon the surface of the first cell in the LEGC stack. The energy gap of each cell in the LEGC stack is <E_{g}^{m}. The one or more cells in the LEGC stack each absorb light with photons of energy greater than or equal to their energy gap and are transparent to and transmit light with photons of energy less than their energy gap. Preferably, the LEGC stack contains at least two cells. Preferably, the energy gap of the cell with the lowest energy gap is sufficiently low to effectively absorb the majority of photons transmitted to it.

The light reflected and/or transmitted by the dichroic mirror can impinge directly upon the surface of the first cell in the appropriate stack. Alternatively, a reflecting mirror can be positioned so that light reflected and/or transmitted by the dichroic mirror is reflected by the reflecting mirror and directed to impinge upon the surface of the first cell in the appropriate stack, i.e., light with photons of energy ≧E_{g}^{m} is directed to impinge upon the surface of the first cell in the MEGC stack and light with photons of energy <E_{g}^{m} is directed to impinge upon the surface of the first cell in the LEGC stack

The silicon cell of the invention is positioned adjacent to the cell with the smallest energy gap of the cells in the MEGC stack, i.e., the last cell in the MEGC stack. “Adjacent” is used herein to indicate that the silicon cell is nearby the last cell in the MEGC stack, but not necessarily contiguous to that cell. Preferably, the silicon cell is contiguous to the last cell in the MEGC stack. The purpose of the silicon cell is to absorb any light transmitted by the MEGC stack and capture at least a portion of the energy contained in that light in order to increase the efficiency of the solar cell. The cross-sectional area of the silicon cell should be at least that of the cells in the MEGC stack and the cell should be positioned so that all the light transmitted by the MEGC stack impinges upon the silicon cell. The transmitted light consists of that portion of the light impinging upon the MEGC stack with photons of energies below the energy gap of the cell in the MEGC stack with the lowest energy gap. The amount of such light depends upon the difference between the energy gap of the cell in the MEGC stack with the lowest energy gap and E_{g}^{m} and by the steepness of the transition region of the dichroic mirror. The silicon cell acts as a scavenger cell to absorb energy that would otherwise have been lost and convert that energy to electricity. Thus the silicon cell contributes to the goal of this architecture for the efficient use of all portions of the solar spectrum and increases the efficiency of the solar cell

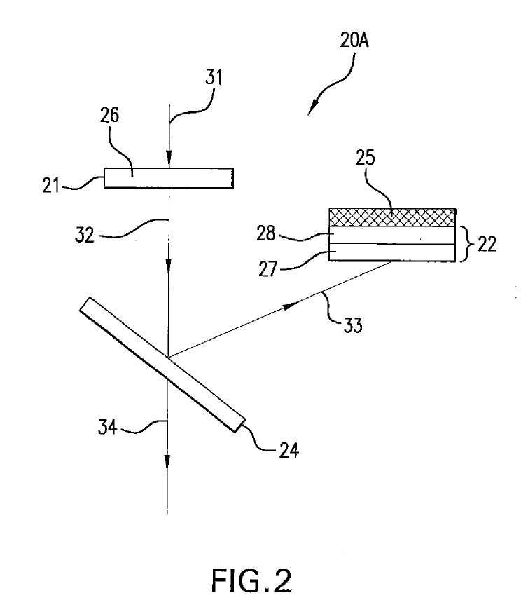

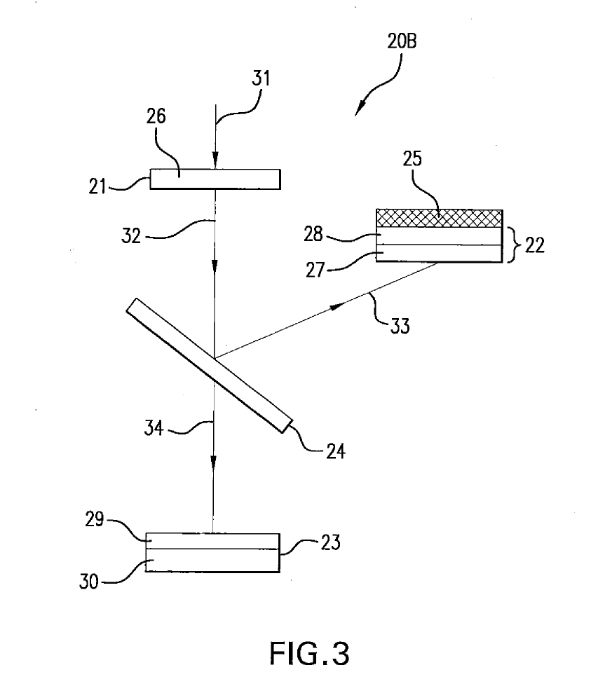

In FIGS. 2 and 3, the same numbers are used to identify the same entities. For, simplicity, the various light beams are represented by a single light ray.

FIG. 2 illustrates an embodiment of the improved solar cell with “HEGC stack-dichroic mirror-MEGC stack” architecture and the silicon scavenger cell. The improved solar cell 20A is comprised of HEGC stack 21, MEGC stack 22, “cold” dichroic mirror 24 and the silicon cell 25 of the invention shown as the cross-hatched area. The HEGC stack 21 as shown contains one cell 26 having an energy gap E_{g}^{h}. The MEGC stack 22 as shown contains two cells 27 and 28 with different energy gaps E_{g}²⁷ and E_{g}²⁸, where E_{g}²⁷ and E_{g}²⁸ are both ≧E_{g}^{m} and <E_{g}^{h} and E_{g}²⁷ is >E_{g}²⁸. The dichroic mirror 24 operates at E_{g}^{m} and reflects light with photons of energy ≧E_{g}^{m} and transmits light with photons of energy <E_{g}^{m}. Solar light 31 impinges upon the surface of the high energy gap cell 26. High energy gap cell 26 absorbs light with photons of energy ≧E_{g}^{h} and transmits light 32 with photons of energy <E_{g}^{h}. The light 32 impinges upon the dichroic mirror 24 which is positioned so that it is not perpendicular to the direction of the light 32. Light 33 with photons of energy ≧E_{g}^{m} is reflected by the dichroic mirror and impinges upon the surface of the first cell 27 of the MEGC stack 22. Cells 27 and 28 each absorb light with photons of energy greater than or equal to their energy gap and are transparent to and transmit light with photons of energy less than their energy gap. The silicon cell 25 is shown contiguous to the last cell in the MEGC stack and receives the light transmitted by the MEGC stack 22 and absorbs the light with photons of energy greater than its 1.12 eV energy gap and provides electricity from the energy that would otherwise have been lost. Light 34 with photons of energy <E_{g}^{m} is transmitted by the dichroic mirror and is arranged to impinge upon other cells.

FIG. 3 illustrates an embodiment of the improved solar cell with “HEGC stack-dichroic mirror-MEGC stack-LEGC stack” architecture and the silicon scavenger cell. The improved solar cell 20B with is comprised of HEGC stack 21, MEGC stack 22, LEGC stack 23, “cold” dichroic mirror 24 and the silicon cell 25 of the invention shown as the cross-hatched area. The HEGC stack 21 as shown contains one cell 26 having an energy gap E_{g}^{h}. The MEGC stack 22 as shown contains two cells 27 and 28 with different energy gaps E_{g}²⁷ and E_{g}²⁸, where E_{g}²⁷ and E_{g}²⁸ are both E_{g}^{m} and <E_{g}^{h} and E_{g}²⁷ is >E_{g}²⁸. The LEGC stack 23 as shown contains two cells 29 and 30 with different energy gaps E_{g}²⁹ and E_{g}³⁹, where E_{g}²⁹ and E_{g}³⁰ are both <E_{g}^{m} and E_{g}²⁹ is >E_{g}³⁰. The dichroic mirror 24 operates at E_{g}^{m} and reflects light with photons of energy ≧E_{g}^{m} and transmits light with photons of energy <E_{g}^{m}. Solar light 31 impinges upon the surface of the high energy gap cell 26. High energy gap cell 26 absorbs light with photons of energy E_{g}^{h} and transmits light 32 with photons of energy <E_{g}^{h}. The light 32 impinges upon the dichroic mirror 24 which is positioned so that it is not perpendicular to the direction of the light 32. Light 33 with photons of energy ≧E_{g}^{g} is reflected by the dichroic mirror and impinges upon the surface of the first cell 27 of the MEGC stack 22. Cells 27 and 28 each absorb light with photons of energy greater than or equal to their energy gap and are transparent to and transmit light with photons of energy less than their energy gap. The silicon cell 25 is shown contiguous to the last cell in the MEGC stack and receives the light transmitted by the MEGC stack 22 and absorbs the light with photons of energy greater than its 1.12 eV energy gap and provides electricity from the energy that would otherwise have been lost. Light 34 with photons of energy <E_{g}^{m} is transmitted by the dichroic mirror and impinges upon the surface of the first cell 29 of the LEGC stack 23. Cells 29 and 30 each absorb light with photons of energy greater than or equal to their energy gap and are transparent to and transmit light with photons of energy less than their energy gap.

Materials suitable for cells for the HEGC stack with energy gaps 2.0 eV can be selected from the III-V GaInP/AlGaInP and AlInGaN material systems. An InGaN cell with an energy gap of 2.4 eV is a preferred cell material. For preparation see, for example, O. Jani et al., Conference Record, 2006 IEEE 4^{th} World Conference on Photovoltaic Energy Conversion, May 10, 2006, Waikoloa, Hawaii. When the HEGC stack contains only one cell, InGaN on a sapphire substrate is preferred. The InGaN-sapphire combination has a low index of refraction and reduces the requirements on the optical anti-reflection coatings used to minimize the reflection of solar light from the cell surface. The sapphire substrate could be shaped to serve as a lens.

Materials suitable for cells for the MEGC stack with energy gaps <2.0 eV and ≧E_{g}^{m} where E_{g}^{m} is ‘about 1.4 eV can be selected from III-V GaInP/GaAsP/GaInAs material system. A GaInP cell with an energy gap of 1.84 eV and a GaAs cell with an energy gap of 1.43 eV are two of the preferred cells for the MEGC stack. A two cell MEGC stack consisting of GaInP/GaAs tandem cells can be prepared using, trimethyl gallium, trimethyl indium, phosphine, arsine and other precursors as described by K. A. Bertness et al., Appl. Phys. Letter 65, 989 (1994).

GaAs is a preferred cell for the cell with the lowest energy gap in a MEGC stack. Therefore, it is preferred for E_{g}^{m} to be about 1.43 eV.

Cells with energy gaps <E_{g}^{m}, where E_{g}^{m} is in the range of from about 1.2 eV to about 1.4 eV, suitable for use in the LEGC stack are silicon cells with an energy gap of 1.12 eV and InGaAs and InGaAsP cells with energy gaps <1 eV. Silicon cells and their preparation are well-known. The InGaAs cells are state of the art devices designed for thermophotovoltaic applications. For preparation see, for example, R. J. Wehrer et al., Conference Record, IEEE Photovoltaic Specialists Conference, 2002, p 884-887.

In one embodiment, the cells in one or more stacks can be electrically connected in series to provide a single output for the stack. The cells in the MEGC stack and the silicon cell adjacent to the MEGC stack can also be electrically connected in series to provide a single output. In a more preferred embodiment, all the individual cells in the HEGC, MEGC and LEGC stacks and the silicon cell adjacent to the MEGC stack are contacted with individual electrical connections. This results in a substantial simplification of the solar cell and provides the opportunity to regulate the voltage across each cell at a value to provide optimum operation of the cell. The cells can be connected to a power combiner that provides a single electrical output for the solar cell at the desired voltage.

Light reflected from the surfaces of cells is a potential source of decreased solar cell efficiency. An anti-reflection coating can be applied to the surfaces of any of the cells upon which light impinges to minimize this loss.

In a preferred embodiment, the improved high efficiency solar cell further comprises an optical element. The intensity or concentration of solar radiation striking a surface is 1×, the normal concentration. It is more difficult and more expensive to achieve high solar cell efficiency with 1× solar light than it is using solar light of higher concentrations. The purpose of the optical element is to collect and concentrate the light impinging upon it and direct the light upon the surface of the first cell in the HEGC stack. The optical element comprises a total internal reflecting concentrator that is a static concentrator. This static concentrator increases the power density of the solar light that can be utilized by the solar cell. It is a wide acceptance—angle concentrator that accepts light from a large portion of the sky. Unlike a tracking concentrator, the static concentrator is able to capture most of the diffuse light, much of which is in the blue to ultraviolet portion of the spectrum. This diffuse light makes up about 10% of the incident power in the solar spectrum. In practice, high levels of concentration are achieved by rejecting light from those portions of the sky in which the power density of the solar radiation is low throughout the year. In this way, concentrations of the solar light are increased by a factor of 10×. Higher concentrations are obtained if the position of the concentrator can be adjusted at some time during the year. Light is transmitted through one surface of the concentrator and that surface is adjacent to the surface of the first cell in the HEGC stack. “Solar light” is used herein to refer to the complete solar spectrum that impinges upon the surface of the first cell in the HEGC stack, no matter what the concentration. Preferably, the concentration is 10× or higher.

What is claimed is:

1. An improved high efficiency solar cell with a “high energy gap cell (HEGC) stack-dichroic mirror-mid energy gap cell (MEGC) stack” architecture comprising:
(a) a HEGC stack that contains one or more cells with different energy gaps arranged vertically in descending order of their energy gaps with the first cell having the largest energy gap of the one or more cells in the HEGC stack, wherein solar light impinges upon the surface of the first cell in the HEGC stack before there is any splitting of the solar light into spectral components, wherein the energy gap of each cell in the HEGC stack is ≧E_{g}^{h} and wherein the one or more cells in the HEGC stack each absorb light with photons of energy greater than or equal to their energy gap and are transparent to and transmit light with photons of energy less than their energy gap thereby providing light transmitted by the HEGC stack;
(b) a dichroic mirror operating at E_{g}^{m} and positioned so that the light transmitted by the HEGC stack impinges upon the dichroic mirror, wherein E_{g}^{m}<E_{g}^{h} and wherein the dichroic mirror provides a separation of the light transmitted by the HEGC stack into two spectral components, one component of light with photons of energy ≧E_{g}^{m} and one component of light with photons of energy <E_{g}^{m} and wherein one of these components is reflected by the dichroic mirror and one is transmitted by the dichroic mirror; and
(c) a MEGC stack that contains one or more cells with different energy gaps arranged vertically in descending order of their energy gaps with the first cell having the largest energy gap of the one or more cells in the MEGC stack, the MEGC stack being positioned so that the component of light with photons of energy ≧E_{g}^{m} impinges upon the surface of the first cell in the MEGC stack, wherein the energy gap of each cell in the MEGC stack is ≧E_{g}^{m} and <E_{g}^{h} and wherein the one or more cells in the MEGC stack each absorb light with photons of energy greater than or equal to their energy gap and are transparent to and transmit light with photons of energy less than their energy gap, the improvement comprising a silicon cell positioned adjacent to the cell with the smallest energy gap of the cells in the MEGC stack.

2. The improved high efficiency solar cell of claim 1, wherein E_{g}^{h}≧2.0 eV and E_{g}^{m} is about equal to the energy gap of the cell with the lowest energy gap in the MEGC stack.

3. The improved high efficiency solar cell of claim 2, wherein the cell with the lowest energy gap is a GaAs cell and E_{g}^{m} is about 1.43 eV.

4. The improved high efficiency solar cell of claim 1, wherein the silicon cell is contiguous to the cell in the MEGC stack with the smallest energy gap.

5. The improved high efficiency solar cell of claim 1, wherein the HEGC stack contains one cell.

6. The improved high efficiency solar cell of claim 5, wherein the MEGC stack contains at least two cells.

7. The high improved efficiency solar cell of claim 1, wherein the MEGC stack contains at least two cells.

8. The improved high efficiency solar cell of claim 1, wherein all the individual cells in the HEGC and MEGC stacks and the silicon cell adjacent to the MEGC stack are contacted with individual electrical connections.

9. The improved high efficiency solar cell of claim 8, further comprising an optical element to collect and concentrate the solar light and direct the concentrated solar light to impinge upon the surface of the first cell in the HEGC stack.

10. An improved high efficiency solar cell with a “high energy gap cell (HEGC) stack-dichroic mirror-mid energy gap cell (MEGC) stack-low energy gap cell (LEGC) stack” architecture comprising:
(a) a HEGC stack that contains one or more cells with different energy gaps arranged vertically in descending order of their energy gaps with the first cell having the largest energy gap of the one or more cells in the HEGC stack, wherein solar light impinges upon the surface of the first cell in the HEGC stack before there is any splitting of the solar light into spectral components, wherein the energy gap of each cell in the HEGC stack is ≧E_{g}^{h} and wherein the one or more cells in the HEGC stack each absorb light with photons of energy greater than or equal to their energy gap and are transparent to and transmit light with photons of energy less than their energy gap thereby providing light transmitted by the HEGC stack;
(b) a dichroic mirror operating at E_{g}^{m} and positioned so that the light transmitted by the HEGC stack impinges upon the dichroic mirror, wherein E_{g}^{m}<E_{g}^{h} and wherein the dichroic mirror provides a separation of the light transmitted by the HEGC stack into two spectral components, one component of light with photons of energy ≧E_{g}^{m} and one component of light with photons of energy <E_{g}^{m} and wherein one of these components is reflected by the dichroic mirror and one is transmitted by the dichroic mirror;
(c) a MEGC stack that contains one or more cells with different energy gaps arranged vertically in descending order of their energy gaps with the first cell having the largest energy gap of the one or more cells in the MEGC stack, the MEGC stack being positioned so that the component of light with photons of energy ≧E_{g}^{m} impinges upon the surface of the first cell in the MEGC stack, wherein the energy gap of each cell in the MEGC stack is ≧E_{g}^{m} and <E_{g}^{h} and wherein the one or more cells in the MEGC stack each absorb light with photons of energy greater than or equal to their energy gap and are transparent to and transmit light with photons of energy less than their energy gap; and
(d) a LEGC stack that contains one or more cells with different energy gaps arranged vertically in descending order of their energy gaps with the first cell having the largest energy gap of the one or more cells in the LEGC stack, the LEGC stack being positioned so that the component of light with photons of energy <E_{g}^{m} impinges upon the surface of the first cell in the LEGC stack, wherein the energy gap of each cell in the LEGC stack is <E_{g}^{m} and wherein the one or more cells in the LEGC stack each absorb light with photons of energy greater than or equal to their energy gap and are transparent to and transmit light with photons of energy less than their energy gap, the improvement comprising a silicon cell positioned adjacent to the cell with the smallest energy gap of the cells in the MEGC stack.

11. The improved high efficiency solar cell of claim 10, wherein E_{g}^{h}≧2.0 eV and E_{g}^{m} is about equal to the energy gap of the cell with the lowest energy gap in the MEGC stack.

12. The improved high efficiency solar cell of claim 11, wherein the cell with the lowest energy gap is a GaAs cell and E_{g}^{m} is about 1.43 eV.

13. The improved high efficiency solar cell of claim 10, wherein the silicon cell is contiguous to the cell in the MEGC stack with the smallest energy gap.

14. The improved high efficiency solar cell of claim 10, wherein the HEGC stack contains one cell.

15. The improved high efficiency solar cell of claim 14, wherein the MEGC stack contains at least two cells and the LEGC stack contains at least two cells.

16. The high improved efficiency solar cell of claim 10, wherein the MEGC stack contains at least two cells and the LEGC stack contains at least two cells.

17. The improved high efficiency solar cell of claim 10, wherein all the individual cells in the HEGC, MEGC and LEGC stacks and the silicon cell adjacent to the MEGC stack are contacted with individual electrical connections.

18. The improved high efficiency solar cell of claim 10, further comprising an optical element to collect and concentrate the solar light and direct the concentrated solar light to impinge upon the surface of the first cell in the HEGC stack.
